(19) United States
(12) Patent Application Publication
(10) Pub. No.: US 2008/0182420 A1
(43) Pub. Date: Jul. 31, 2008

(54) ION BEAM TREATMENT FOR THE STRUCTURAL INTEGRITY OF AIR-GAP III-NITRIDE DEVICES PRODUCED BY THE PHOTOELECTROCHEMICAL (PEC) ETCHING

(75) Inventors: Evelyn L. Hu, Goleta, CA (US); Shuji Nakamura, Santa Barbara, CA (US); Yong Seok Choi, Goleta, CA (US); Rajat Sharma, Goleta, CA (US); Chiou-Fu Wang, Goleta, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 11/940,876

(22) Filed: Nov. 15, 2007

Related U.S. Application Data
(60) Provisional application No. 60/866,027, filed on Nov. 15, 2006.

(51) Int. Cl. H01L 21/302

(52) U.S. Cl. 438/712; 257/E21.214

(57) ABSTRACT

A method for ensuring the structural integrity of III-nitride opto-electronic or opto-mechanical air-gap nano-structured devices, comprising (a) performing ion beam implantation in a region of the III-nitride opto-electronic and opto-mechanical air-gap nano-structured device, wherein the milling significantly locally modifies a material property in the region to provide the structural integrity; and (b) performing a band-gap selective photo-electro-chemical (PEC) etch on the III-nitride opto-electronic and opto-mechanical air-gap nano-structured device. The method can be used to fabricate distributed Bragg reflectors or photonic crystals, for example. The method also comprises the suitable design of distributed Bragg reflector (DBR) structures for the PEC etching and the ion-beam treatment, the suitable design of photonic crystal distributed Bragg reflector (PCDBR) structures for PEC etching and the ion-beam treatment, the suitable placement of protection layers to prevent the ion-beam damage to optical activity and PEC etch selectivity, and a suitable annealing treatment for curing the material quality after the ion-beam treatment.

### CROSS-REFERENCE TO RELATED APPLICATIONS

This application claims the benefit under 35 U.S.C. Section 119(e) of the following co-pending and commonly-assigned U.S. provisional patent application:

Provisional Application Ser. No. 60/866,027, filed Nov. 15, 2006, by Evelyn L. Hu, Shuji Nakamura, Yong Seok Choi, Rajat Sharma, and Chio-Fu Wang, entitled “ION BEAM TREATMENT FOR THE STRUCTURAL INTEGRITY OF AIR-GAP III-NITRIDE DEVICES PRODUCED BY PHOTOELECTROCHEMICAL (PEC) ETCHING,” attorneys' docket number 30794.201-US-P1 (2007-161-1);

which application is incorporated by reference herein.

This application is related to the following co-pending and commonly-assigned applications:

U.S. Utility application Ser. No. 11/263,314, filed on Oct. 31, 2005, by Evelyn L. Hu, Shuji Nakamura, Elaine D. Haberer, and Rajat Sharma, entitled “CONTROL OF PHOTOELECTROCHEMICAL (PEC) ETCHING BY MODIFICATION OF THE LOCAL ELECTROCHEMICAL POTENTIAL OF THE SEMICONDUCTOR STRUCTURE RELATIVE TO THE ELECTROLYTE”, attorney's docket number 30794.124-US-U1 (2005-207-2), which application claims the benefit under 35 U.S.C Section 119(e) of U.S. Provisional Application Ser. No. 60/624,308, filed Nov. 2, 2004, by Evelyn L. Hu, Shuji Nakamura, Elaine D. Haberer, and Rajat Sharma, entitled “CONTROL OF PHOTOELECTROCHEMICAL (PEC) ETCHING BY MODIFICATION OF THE LOCAL ELECTROCHEMICAL POTENTIAL OF THE SEMICONDUCTOR STRUCTURE RELATIVE TO THE ELECTROLYTE”, attorney's docket number 30794.124-US-P1 (2005-207-1);

which applications are incorporated by reference herein.

### STATEMENT REGARDING FEDERALLY SPONSORED RESEARCH AND DEVELOPMENT

This invention was made with Government support under Grant No. DE-FC26-01NT41203 awarded by the Department of Energy. The Government has certain rights in this invention.

### BACKGROUND OF THE INVENTION

1. Field of the Invention

This invention relates to a scheme to ensure the structural integrity of opto-electronic as well as opto-mechanical air-gap nano-structured devices, based III-nitride compound semiconductor materials, wherein a highly selective local photo-electro-chemical (PEC) etching is applied.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

Prior work has demonstrated the possibility of forming membranes and large undercut structures in the III-nitride materials system, through the use of bandgap-selective PEC wet etching [9-11, 13], with the selective removal of a sacrificial layer. Membranes as large as several millimeters square in area have been formed through this technique, and rudimentary air-gap Distributed Bragg Reflectors (DBRs), have also been attempted. The primary limitations to prior work has been (1) limitations in etch selectivity, (2) bowing and warping of the membranes due to inherent strain, and (3) stiction of closely space membrane layers (as in DBRs).

The invention described here provides solutions to limitations (2) and (3). While air-gap DBR structures have been formed in other material systems, through simple, selective wet chemical etch processes (i.e. not photo-induced), the problems (1), (2) and (3) listed above are also limitations to those processes. The photo-enhanced nature of the PEC etch process, and the curtailment of etching through the creation of defects in the material, provides a unique means of controlling the structural integrity that is not available in non photo-induced processes.

The etching mechanism relies heavily on the absorption of incident light, and the electrochemical potential of the semiconductor material relative to the electrolyte. PEC etching can, therefore, be defect-selective [18], dopant-selective [19], and band-gap selective [3]. In particular, various III-nitride air-gap microstructures [1-6] have been demonstrated by utilizing the band-gap selectivity as well as the strategic placement of an electrode. However, the prior schemes cannot be applicable to realize various air-gap III-nitride microstructures, unless the reliable scheme presented here is utilized, to guarantee the structural integrity of the high-strain III-nitride material. This invention is important for realizing multifunction devices for opto-electronic as well as opto-mechanical applications.

### SUMMARY OF THE INVENTION

The present invention describes a scheme to ensure the structural integrity of opto-electronic, as well as opto-mechanical air-gap nano-structured devices, using III-nitride compound semiconductor materials, wherein a highly selective local PEC etching is applied. This is accomplished through:

1) The suitable design of DBR structures for PEC etching and the ion-beam treatment.

2) The suitable design of photonic crystal distributed Bragg reflector (PCDBR) structures, for PEC etching and the ion-beam treatment.

3) The suitable ion-beam treatment, on a local area of device surface, to prevent PEC damage.

4) The suitable placement of protection layer(s), to prevent the ion-beam damage to optical activity and PEC etch selectivity.

5) A suitable annealing treatment for curing the material quality after the ion-beam treatment.

6) A suitable scheme to inspect the etch condition and the effect of ion-beam treatment during the fabrication.

### BRIEF DESCRIPTION OF THE DRAWINGS

FIGS. 1A-1C illustrate a method for ensuring the structural integrity of III-nitride opto-electronic or opto-mechanical air-gap nano-structured devices.

FIGS. 2A-2C illustrate a method for ensuring the structural integrity of III-nitride opto-electronic, or opto-mechanical air-gap nano-structured devices, wherein milled material is not removed prior to etching.

FIGS. 3A-3b are scanning electron micrograph (SEM) images showing an AlGaN/InGaN epistructure before PEC etching (FIG. 3A), and after PEC etching (FIG. 3B).

FIGS. 4A-4F illustrate the process used to fabricate a large-area air-gap III-nitride DBR structures.

FIGS. 5A-5F illustrate the process used to fabricate an active air-gap III-nitride DBR structure which can be optically pumped.

FIGS. 6A-6F illustrate the process used to fabricate an active air-gap III-nitride DBR structure, comprising a vertical cavity surface emitting laser (VCSEL).

FIGS. 7A-7D are SEM images and optical images of active air-gap III-nitride DBR structures.

FIGS. 8A and 8B are angle resolved photoluminescence (PL) spectra images before and after PEC etching.

FIG. 9 is a SEM image of a VCSEL fabricated according to the method of the present invention.

FIGS. 10A-10F illustrate the process used to fabricate an air-gap III-nitride DBR LED which can be electrically pumped.

FIGS. 11A-11D illustrate device performance, before and after the formation of a air/AlGaN DBR structure.

FIGS. 12A-12F illustrate the process used to fabricate a 2D photonic crystal air-gap III-nitride DBR LED, which can be electrically pumped.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

Advances in III-nitride processing have led to the formation of air-gap DBRs [1], high-quality microdisk lasers [2,3], and CAVET [4], and free-standing photonic crystal (PC) membrane nanocavities [5,6]. In the present invention, the unique control over the selective removal of embedded materials is obtained by a PEC wet-etching technique [7-16]. This selective wet etching can allow the larger index contrast between the air and the remaining material for higher index contrast in the DBRs, and therefore achievement of higher reflectivity with fewer mirror layers.

Combined with air-gap DBRs, the free-standing active membrane, as well as the free-standing active PC membrane, will create efficient microcavity LEDs. The integration with dielectric DBRs will be useful for developing low-threshold, and mechanically tunable, VCSELs based on III-nitride materials.

The main challenge in developing the air-gap nano-architectures is the significant warping or bowing of the remaining layers after the PEC etch process. This originates from the as-grown intrinsic strain in III-nitride hetero-structures, such as (GaN-InGaN-AlGaN), and the spatially non-uniform removal of the sacrificial layers. As a result, the dimension, the design, and the stability of the devices should be substantially compromised over the potential of air-gap architectures.

The invented technique of the focused-ion-beam (FIB) treatment is a viable method for improving the structural integrity of the III-nitride-based air-gap microstructures. The FIB treatment greatly enhances the local control of PEC etch process to allow various air-gap microstructures. Furthermore, it can be applied to provide efficient current injection, for better performance, and improved surface passivation, for long-term stability. The presented scheme, based on the FIB treatment, can be replaced by an ion-implantation technique [17], to create a process more compatible with standard manufacturing techniques. The invention can further promote the structural integrity of large undercut structures, more generally used for mechanical (e.g. micro-electro-mechanical systems, or MEMS), or optical devices.

General Process Steps

This invention provides a way of ensuring structural integrity of undercut structures, by the selective placement of vertical, supporting ‘struts’, formed through ion-damage of selective regions of the material. PEC wet etching relies on the light-induced generation of excess holes to drive the etch chemistry. As has been demonstrated, excess trapping of the photogenerated holes will inhibit PEC etching [20]. For example, ion implantation in general, above a threshold dose, can produce traps that will inhibit PEC etching.

FIB implantation can achieve the same end result without the necessity of masking the sample. A particular implementation of the process is described below, where the heterostructure is designed to allow bandgap-selective PEC etching. Additional layers are introduced, to prevent ion damage from compromising the optically active area of the device.

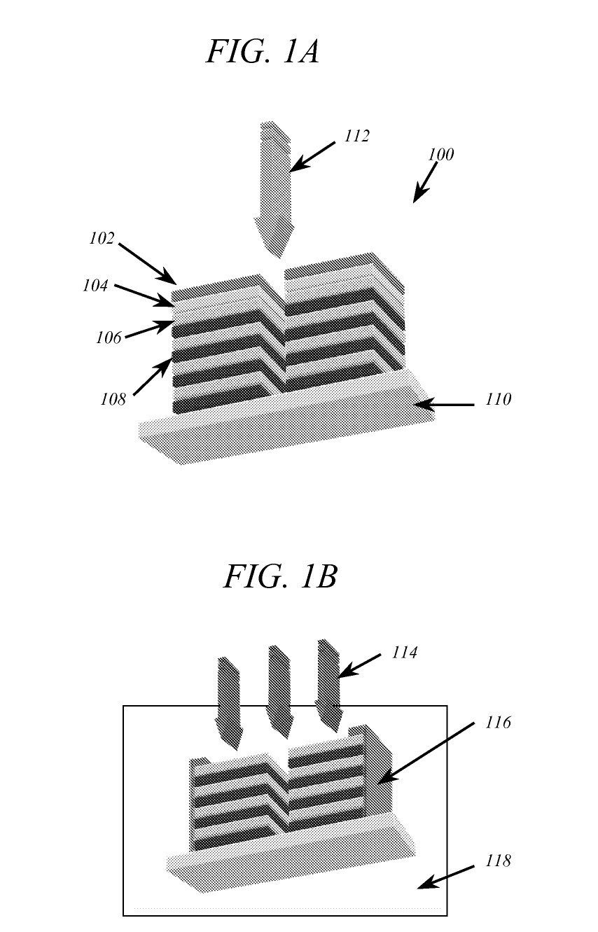

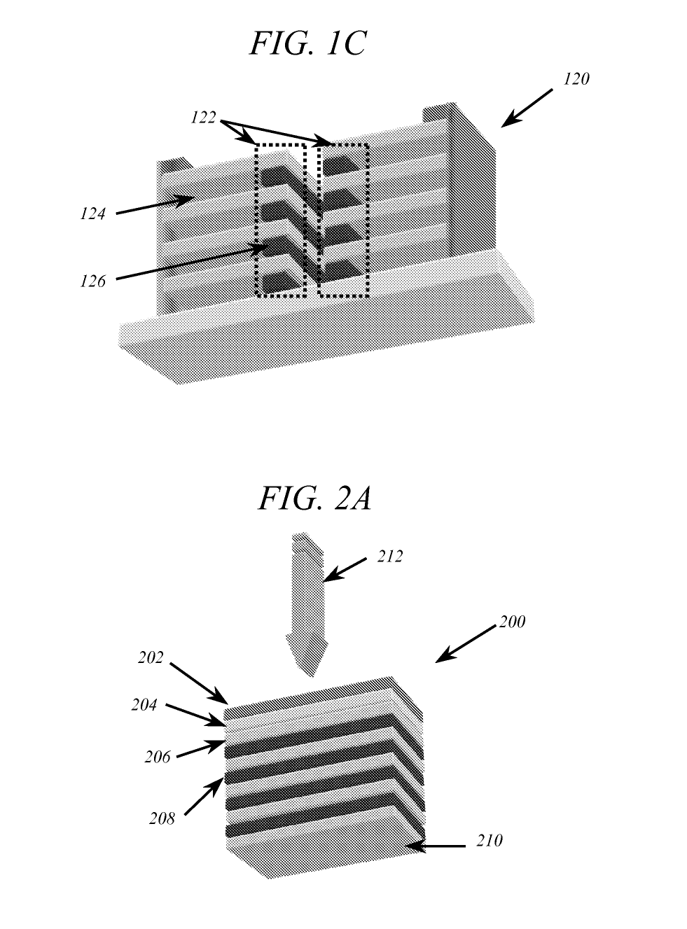

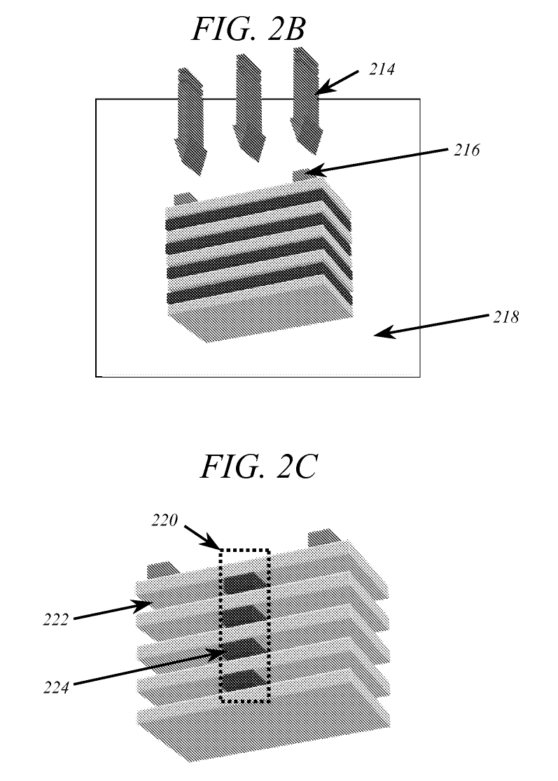

As a result, this region withstands the band-gap selective PEC etching and is able to serve as the structural support, as shown in FIGS. 1A-1C. By optimizing the acceleration voltage and the dose, damage to the optical activity can be minimized, as shown in FIGS. 2A-2C.

In both examples, the III-nitride opto-electronic or opto-mechanical air-gap nano-structured device should be suitably designed for both the PEC etching and the ion beam treatment. Moreover, in both examples, a protection layer may be placed in selected areas of the III-nitride opto-electronic or opto-mechanical air-gap nano-structured device to prevent the ion beam treatment from damaging optical activity and PEC etch selectivity.

Thus, FIGS. 1A-1C schematically illustrate a method for enhancing the structural integrity of III-nitride opto-electronic or opto-mechanical air-gap nano-structured devices. The III-nitride-based air-gap microstructures 100 illustrated in FIG. 1A has a Ni or Ti layer 102, an SiO₂ layer 104, an AlGaN layer 106, an InGaN layer 108, and a GaN layer 110 formed by FIB milling 112. FIG. 1B illustrates a PEC etch step 114, a Ti/Pt electrode layer 116, and a HCI:DI electrolyte 118. FIG. 1C illustrates the final structure 120 having supports 122, air gaps 124, and PECT etch stops 126.

FIG. 1A represents a first step of performing an ion beam treatment, namely a high-dose/high-voltage FIB milling 112, in a region of the III-nitride opto-electronic or opto-mechanical air-gap nano-structured device 100 (e.g., the surface), wherein the ion beam treatment locally modifies a material property in the region by making the region resistant to PEC etching, thereby enhancing the structural integrity. Consequently, the region where the FIB milling 112 is performed comprises an ion-damaged region.

FIG. 1B represents a second step of performing a band-gap selective PEC etch 114 on the III-nitride opto-electronic or opto-mechanical air-gap nano-structured device 100, using illumination (λ>400 nm), wherein the region is not significantly etched because of the ion beam treatment.

FIG. 1C shows the resulting structure 120, having supports 122 in the FIB region, air gaps 124, and PEC etch stops 126. Consequently, the supports 122 in the FIB regions comprise supporting struts that enhance the structural integrity of undercut structures of the III-nitride opto-electronic or opto-mechanical air-gap nano-structured device 100. Note also, that the III-nitride opto-electronic or opto-mechanical air-gap nano-structured device may be annealed for curing material quality after the ion beam treatment.

FIGS. 2A-2C schematically illustrate another method for the present invention, wherein the material is not removed after step 1, in contrast to the method of FIG. 1. Thus, FIG. 2A illustrates a III-nitride-based air-gap microstructure 200 having a Ni or Ti layer 202, an SiO₂ layer 204, an AlGaN layer 206, an InGaN layer 208, and a GaN layer 210 formed by a low dose FIB treatment 212. FIG. 2B illustrates a PEC etch step 214 (e.g., via illumination [λ>400 nm]), a Ti/Pt electrode layer 216, and a HCI:DI (hydrochloric:deionized water) electrolyte 218. FIG. 2C illustrates the final structure having support 220, air gaps 222, and PEC etch stops 224.

In the present invention, illustrated, for example, in FIGS. 1A-1C and 2A-2C:

(1) An FIB (gallium source) 114/214 is used to introduce the point defects into the as-grown material 100/200. The damaged material becomes resistant to PEC etching 114/214. These FIB regions serve as the structural support 120/220.

(2) An SiO₂ layer 104/204 is used to keep the FIB damage from encroaching into the vertical direction. The SiO₂ layer 104/204 is prepared using a plasma-enhanced chemical vapor deposition system.

(3) A Ni or Ti layer 102/202 is used to obtain a high-contrast electron/ion micrograph during the FIB treatment 112/212, as well as to keep the FIB damage from encroaching into the vertical direction. The Ni layer 102/202 is prepared using an electron-beam deposition system.

(4) An AlGaN layer 106/206 serves as the etch stop during the PEC process 112/212, due to its high bandgap. The AlGaN layer 106/206 is grown using a metal-organic chemical-vapor deposition (MOCVD) system.

(5) An InGaN layer 108/208 is used as the sacrificial layer, due to its low bandgap with respect to AlGaN and GaN material. The AlGaN 108/208 is grown by MOCVD.

(6) A GaN layer 110/210 is used as the buffer for the growth of InGaN/AlGaN heterostructures. The GaN layer 110/210 is grown on sapphire by MOCVD.

(7) A Ti/Pt layer 116/216 is used as the electrode that removes excess electrons, while the holes react with electrolyte 118/218 to support oxidation and wet etching. The Ti/Pt layer 116/216 is prepared using an electron-beam deposition system.

(8) HCl:DI water 118/218 is used as the electrolyte, as well as the etch solution, for the PEC wet etch process 114/214.

(9) Illumination is achieved by filtering an Xe lamp using a GaN filter.

(10) Air gap(s) 124/222 are introduced as the result of the PEC undercut wet etching 114/214.

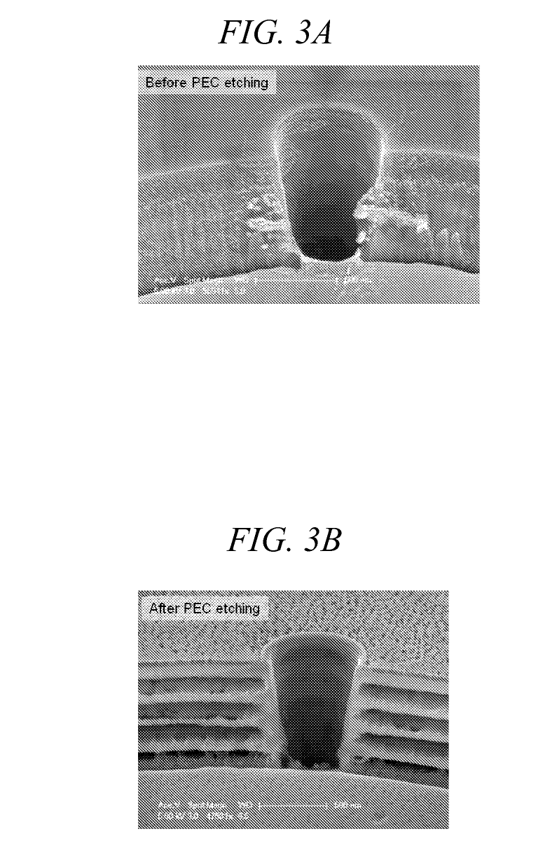

FIGS. 3A and 3B are SEM images of the III-nitride opto-electronic or opto-mechanical air-gap nano-structured devices. FIG. 3A shows the AlGaN/InGaN epistructure after the FIB milling process 112 and before PEC wet etching 114. FIG. 3B shows the air/AlGaN DBR structures 122 produced by the PEC wet etching process 114. The thin layer (50˜100 nm) round hole formed by the FIB milling process is preserved during the PEC etching process 114. This can provide good structural support for the air-gap III-nitride microstructures.

One approach is described above. Four other typical fabrication processes are described below.

Specific Fabrication Techniques

Process 1: Fabrication of a Large-Area Air-Gap III-Nitride DBR

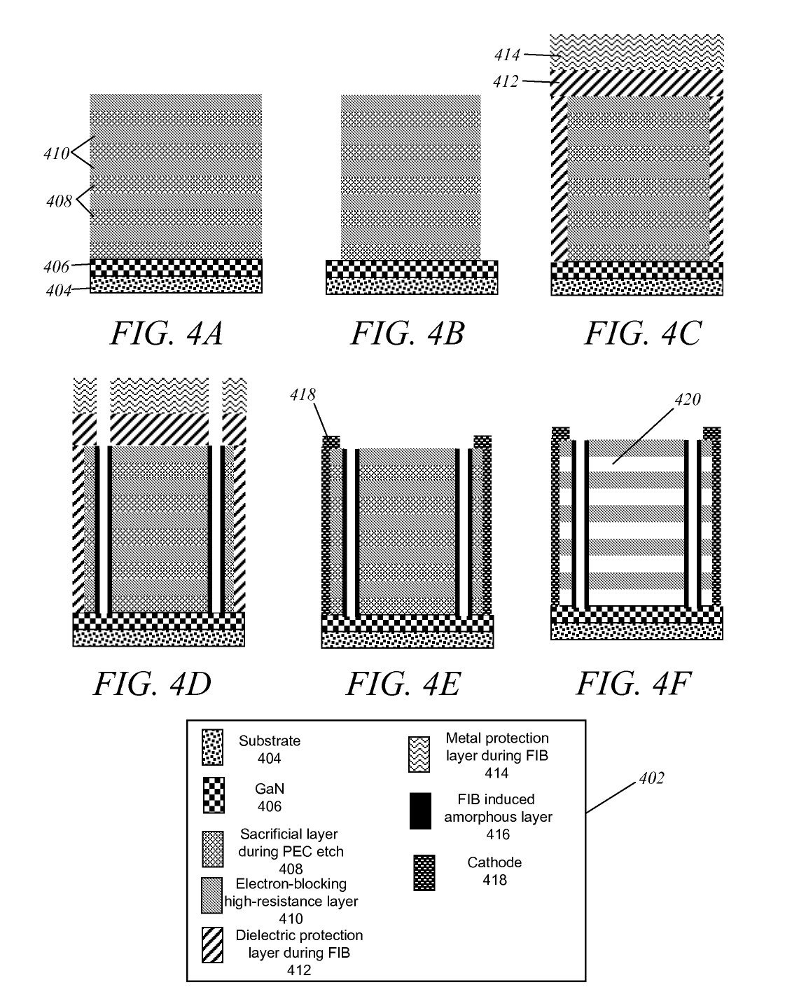

FIGS. 4A-4F are cross-sections showing the layers that illustrate the process used to fabricate a large area air-gap III-nitride DBR structure. The legend 402 describes the different layers shown in FIGS. 4A-4F.

(1) The material structure is shown in FIG. 4A. Each layer is labeled with material composition and doping, as well as layer type. The material is grown by MOCVD on a sapphire substrate 404. The material may be comprised of 1-2 μm GaN 406, sacrificial layers 408 used during a PEC etch (e.g., 100 nm InGaN layers), and electron-blocking high resistance layers 410 (e.g., 120 nm Al(8%)Ga(92%)N layers).

(2) As shown in FIG. 4B, the mesa structure is formed by a standard photo/e-beam-lithography and reactive dry-etching technique.

(3) The dielectric (˜200 nm SiOₓ or SiNₓ) protection layer 412, and the metallic (˜100 nm Ti) protection layer 414, are deposited on the sample to prevent any damage by the FIB irradiation, as shown in FIG. 4C.

(4) The FIB milling is performed at ˜30 kV and ˜30 pA. The FIB patterns can be a circular hole, a line, a rectangle, a circular trench, and their combination, as shown in FIG. 4D (i.e., as an FIB induced amorphous layer 416).

(5) The FIB protection layers 412 and 414 are removed using hydrofluoric (HF) acid.

(6) The sample is annealed at ˜600° C. for 30 minutes to cure/strengthen the material quality.

(7) Using photo-lithography and metal lift-off techniques, the cathode 418 (˜10 nm Ti and ˜300 nm Pt) is deposited around the mesa as shown in FIG. 4E.

(8) The bandgap selective PEC etching is performed using 1000 W Xe lamp irradiation and a ˜0.004M HCl electrolyte solution in DI water.

(9) FIG. 4F shows the large area air-gap/AlGaN DBR 420 fabricated using this method, where the FIB region provides the structural support.

Process 2: Fabrication of an Active Air-Gap III-Nitride DBR Structure and VCSEL Capable of being Optically Pumped.

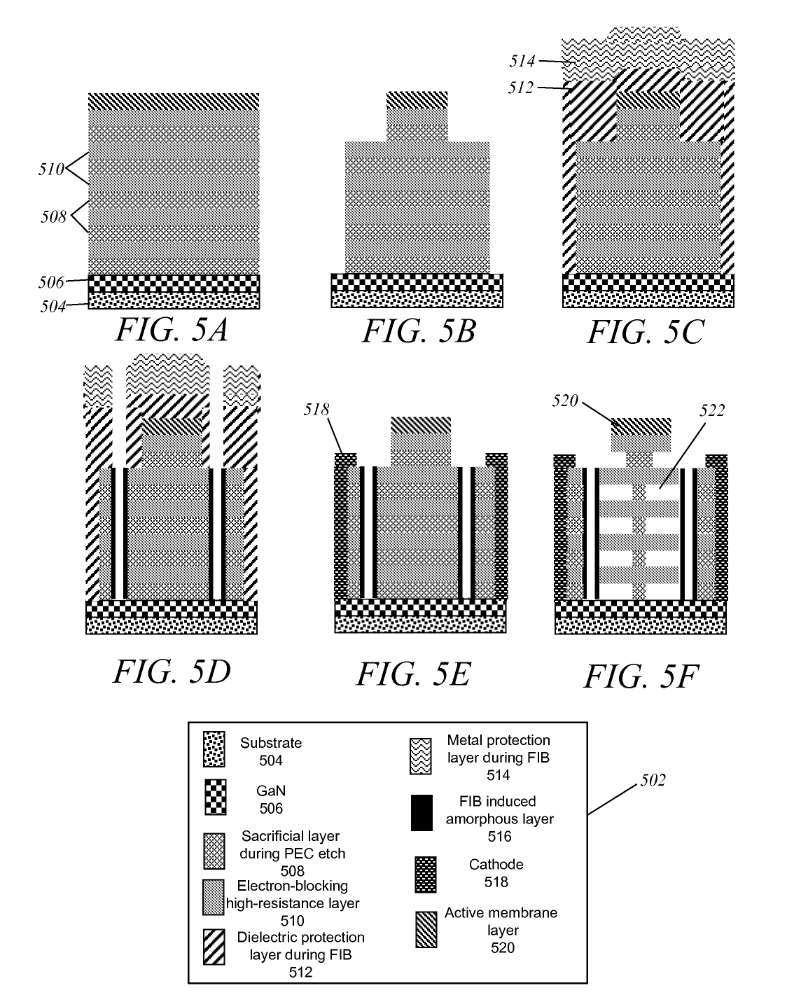

FIGS. 5A-5F are cross-sections showing the layers that illustrate the process used to fabricate an active air-gap III-nitride DBR structure capable of being optically pumped.

(1) The material structure is shown in FIG. 5A. Each layer is labeled with material composition and doping, as well as layer type. The material is grown by MOCVD on a sapphire substrate 504. The material may be comprised of 1-2 μm GaN 506, sacrificial layers 508 used during a PEC etch (e.g., 100 nm InGaN layers), and electron-blocking high resistance layers 510 (e.g., 120 nm Al(8%)Ga(92%)N layers).

(2) The mesa structure for the active membrane layer is formed by standard photo/e-beam-lithography and chlorine-based reactive dry-etching techniques.

(3) The mesa structure for the bottom DBR (5 period AlGaN/InGaN layer) 510 region, is fabricated by standard photo/e-beam-lithography and chlorine-based reactive dry-etching techniques.

(4) FIG. 5B shows the sample structure after steps (2) and step (3) above.

(5) The dielectric (˜200 nm SiOₓ or SiNₓ) protection layer 512, and the metallic (˜100 nm Ti) protection layer 514, are deposited on the sample to prevent any damage by the focused ion beam irradiation, as shown in FIG. 5C.

(6) The FIB milling is performed at ˜30 kV and ˜30 pA. The FIB patterns can be a circular hole, a line, a rectangle, a circular trench, or their combination, as shown in FIG. 5D (i.e., as an FIB induced amorphous layer 516).

(7) The FIB protection layers 512 and 514 are removed using HF.

(8) The sample is annealed at ˜600° C. for 30 minutes to cure/strengthen the material quality.

(9) Using standard photo-lithography and the metal lift-off, the cathode 518 (˜10 nm Ti and ˜300 nm Pt) is deposited around the mesa as shown in FIG. 5E.

(10) The bandgap selective PEC etching is performed, using 1000 W Xe lamp irradiation and the ˜0.004M HCl electrolyte solution in DI water.

(11) FIG. 5F shows the final structure, where the active membrane 520 with InGaN pedestal 508 is on top of the air-gap/AlGaN DBR 522.

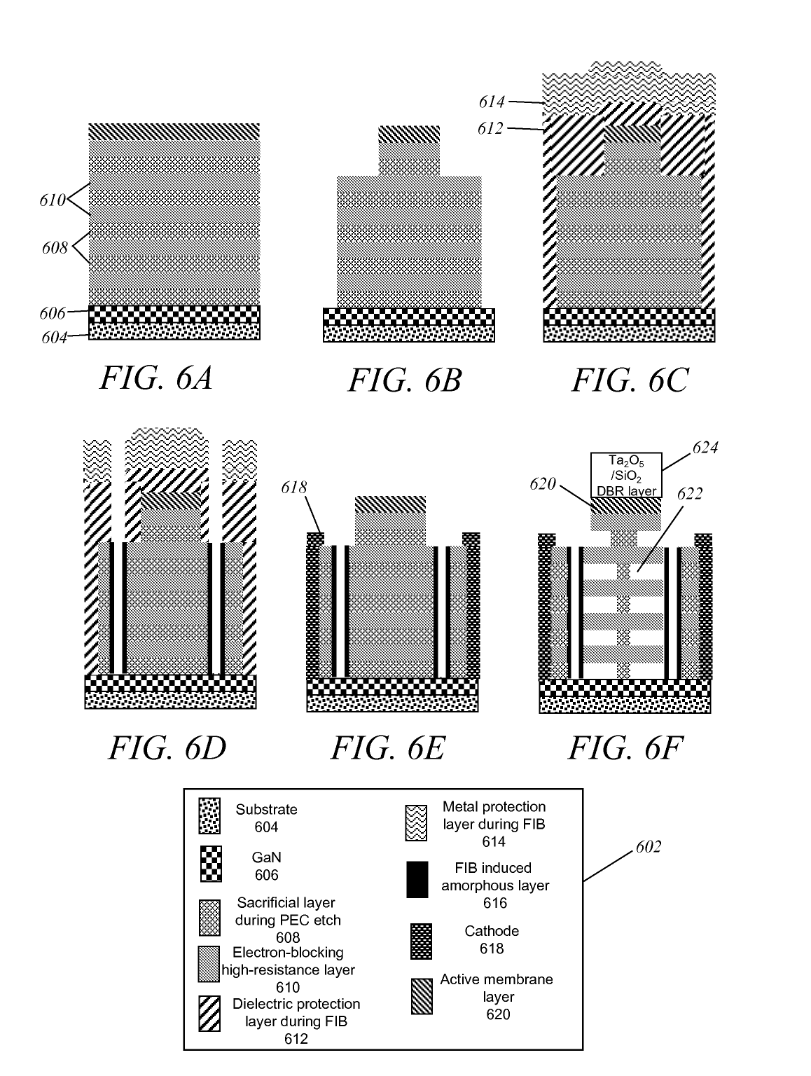

The VCSEL structure shown in FIGS. 6A-6F can be fabricated using the same steps (1) to (11), followed by the deposition of dielectric DBR (˜5 periods 75 nm SiO₂ and 50 nm Ta₂O₅) layers 624 on top. Thus, FIGS. 6A-6F are cross-sections showing the layers that illustrate the process used to fabricate an active air-gap III-nitride DBR structure, comprising a VCSEL capable of being optically pumped:

(1) The material structure is shown in FIG. 6A. Each layer is labeled with material composition and doping, as well as layer type. The material is grown by MOCVD on a sapphire substrate 604. The material may be comprised of 1-2 μm GaN 606, sacrificial layers 608 used during a PEC etch (e.g., 100 nm InGaN layers), and electron-blocking high resistance layers 610 (e.g., 120 nm Al(8%)Ga(92%)N layers).

(2) The mesa structure for the active membrane layer is formed by standard photo/e-beam-lithography and chlorine-based reactive dry-etching techniques.

(3) The mesa structure for the bottom DBR (5 period AlGaN/InGaN layer) 610 region, is fabricated by standard photo/e-beam-lithography and chlorine-based reactive dry-etching techniques.

(4) FIG. 6B shows the sample structure after steps (2) and step (3) above.

(5) The dielectric (˜200 nm SiOₓ or SiNₓ) protection layer 612, and the metallic (˜100 nm Ti) protection layer 614, are deposited on the sample to prevent any damage by the focused ion beam irradiation, as shown in FIG. 6C.

(6) The FIB milling is performed at ˜30 kV and ˜30 pA. The FIB patterns can be a circular hole, a line, a rectangle, a circular trench, or their combination, as shown in FIG. 6D (i.e., as an FIB induced amorphous layer 616).

(7) The FIB protection layers 612 and 614 are removed using HF.

(8) The sample is annealed at ˜600° C. for 30 minutes to cure/strengthen the material quality.

(9) Using standard photo-lithography and the metal lift-off, the cathode 618 (˜10 nm Ti and ˜300 nm Pt) is deposited around the mesa as shown in FIG. 6E.

(10) The bandgap selective PEC etching is performed, using 1000 W Xe lamp irradiation and the ˜0.004M HCl electrolyte solution in DI water.

(11) FIG. 6F shows the final structure, where the active membrane 620 with InGaN pedestal 608 is on top of the air-gap/AlGaN DBR 622 with dielectric DBR layers 624 on top.

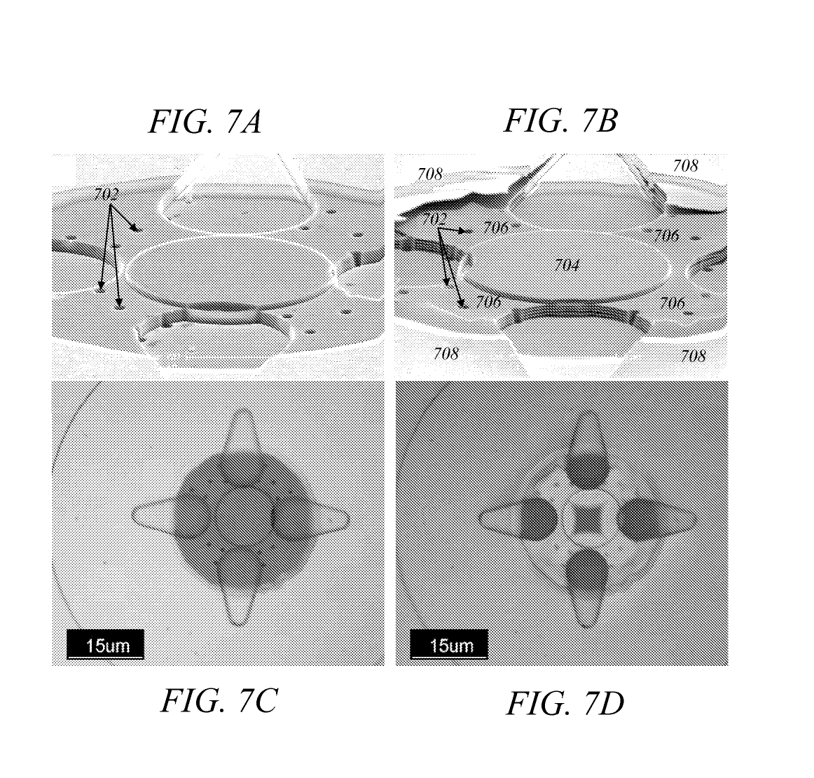

FIGS. 7A-7D are SEM and optical images of the fabricated active air-gap III-nitride DBR structure, where the structure can be optically pumped. SEM images of the structure before (FIG. 7A) and after (FIG. 7B) the formation of the air/AlGaN DBR by the bandgap-selective PEC wet etching are illustrated. In addition, optical images of the structure before (FIG. 7C) and after (FIG. 7D) the PEC etching are illustrated. The undercut region is bright due to the high reflectivity.

Thus, to improve the structural integrity after the PEC etching, FIB milling of small holes 702 around the DBR region was performed, as shown in FIG. 7A. Once the InGaN layers are replaced by air, the large strain, originally due to the lattice mismatch between AlGaN and InGaN, would produce cracking or collapsing. However, the holes 702 produced by FIB milling withstand the etching and support all the layers under the active membrane layer 704. The formation of the air/AlGaN DBR 706, cathode 708, as well as the uniform undercut etch result, can be seen in FIG. 7D.

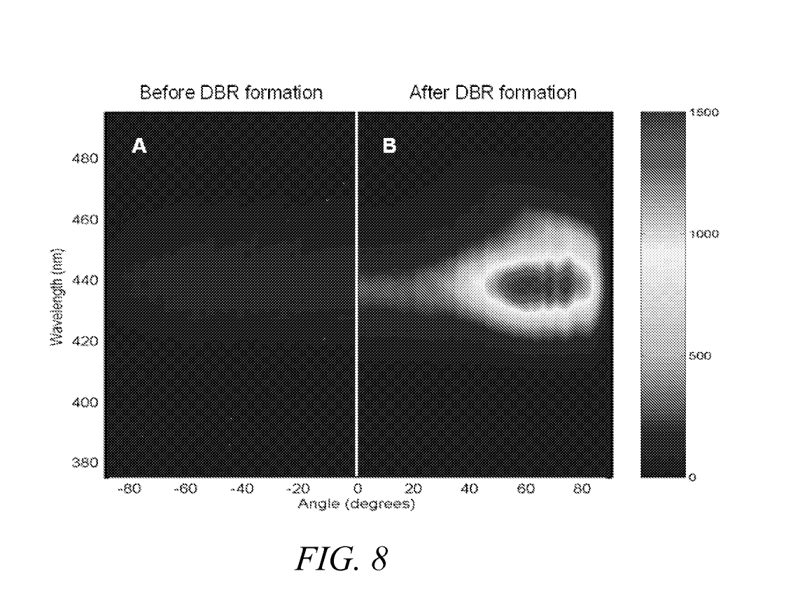

FIGS. 8A and 8B are angle-resolved PL spectra images of the fabricated structure, before (FIG. 8A) and after (FIG. 8B) the bandgap-selective PEC etching, demonstrating the improved extraction efficiency (˜3-4 times improvement). The air/AlGaN DBR under the active membrane layer results in the larger extraction to the specific angle.

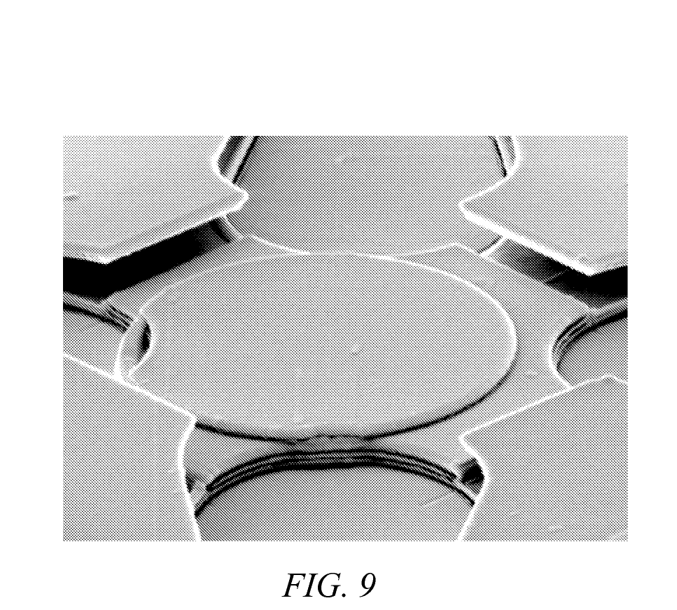

FIG. 9 shows a SEM image of the fabricated VCSEL structures, which are capable of being optically pumped. The bottom DBR is comprised of 5 periods of air and AlGaN layers while the top DBR is comprised of 3 periods of Ta₂O₅ and SiO₂, produced by the e-beam evaporator. The air-gap III-nitride microstructure withstands the heating during the e-beam evaporation, and results in a good structural quality. The period of dielectric DBR can be optimized further to increase the reflectivity to 95%.

Process 3: Fabrication of an Air-Gap III-Nitride DBR LED Capable of being Optically Pumped.

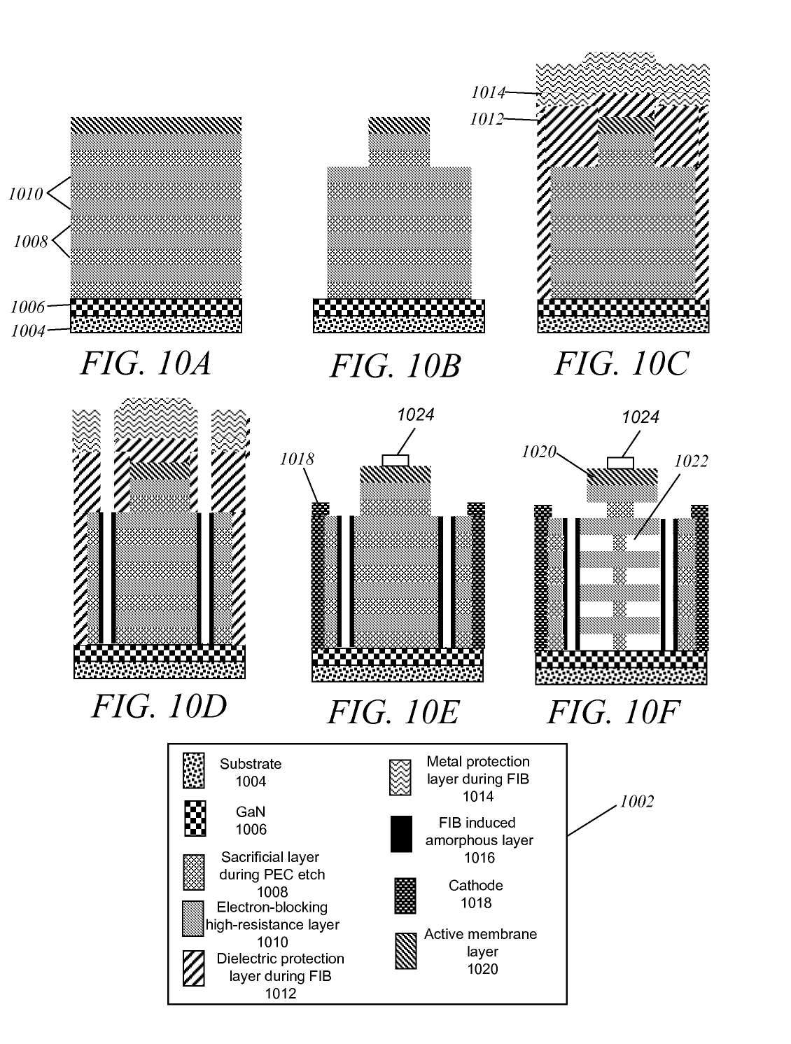

FIGS. 10A-10F are cross-sections showing the layers that illustrate the process used to fabricate an air-gap III-nitride DBR LED capable of being optically pumped.

(1) The material structure is shown in FIG. 10A. Each layer is labeled with material composition and doping, as well as layer type. The material is grown by MOCVD on a sapphire substrate 1004. The material may be comprised of 1-2 μm GaN 1006, sacrificial layers 1008 used during a PEC etch (e.g., 100 nm InGaN layers), and electron-blocking high resistance layers 1010 (e.g., 120 nm Al(8%)Ga(92%)N layers).

(2) The mesa structure for the active membrane layer is formed by standard photo/e-beam-lithography, and a chlorine-based reactive dry-etching technique.

(3) The mesa structure for the bottom DBR (5 period AlGaN/InGaN layer) 1008/1010 region is fabricated by standard photo/e-beam-lithography and chlorine-based reactive dry-etching techniques.

(4) FIG. 10B shows the sample structure after step (2) and step (3).

(5) The dielectric (˜200 nm SiOₓ or SiNₓ) protection layer 1012, and the metallic (˜100 nm Ti) protection layer 1014, are deposited on the sample to prevent any damage by the FIB irradiation as shown in FIG. 10C.

(6) The FIB milling is performed at ˜30 kV and ˜30 pA. The FIB patterns can be a circular hole, a line, a rectangle, a circular trench, and/or their combination, as shown in FIG. 10D (i.e., as an FIB induced amorphous layer 1016).

(7) The FIB protection layers 1012 and 1014 are removed using hydrofluoric acid (HF).

(8) The sample is annealed at ˜600° C. for 15 minutes to activate the p⁺⁺ GaN 1024 on top of each device.

(9) Using standard photo/e-beam-lithography and the metal lift-off, the transparent metal contact 1024 (˜5 nm Pd and ˜10 nm Au) is deposited on the p⁺⁺GaN, as shown in FIG. 10E. The metal contact 1024 can be replaced by Indium Tin Oxide (ITO) or Zinc Oxide (ZnO) materials.

(10) Using photo-lithography and metal lift-off techniques, the cathode 1018 (˜10 nm Ti and ˜300 nm Pt) is deposited around the mesa.

(11) The bandgap selective PEC etching is performed using 1000 W Xe lamp irradiation and the ˜0.004M HCl electrolyte solution in DI water.

(12) FIG. 10F shows the final structure, comprising the active membrane 1020 with InGaN pedestal on top of the air-gap/AlGaN DBR 1022.

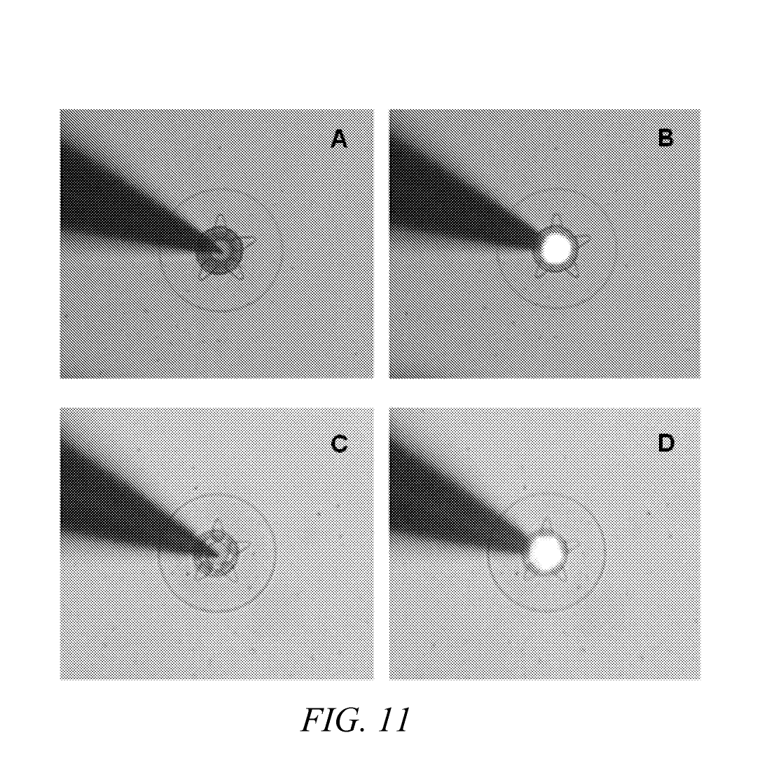

FIGS. 11A-11D show the device performance before and after the formation of the air-gap/AlGaN DBR LED structure. FIG. 11A illustrates the electroluminescence at low current and FIG. 11B illustrates the electroluminescence at high current injection before the PEC etching. PEC etching for 1 hour was performed, which replaced 50 percent of the InGaN layer by air. The carriers are injected from the cathode and recombine in the active membrane layer right under the transparent p-type material. In FIG. 11C, the formation of the air/AlGaN DBR structure can be seen from the undercut etch front. In FIG. 11D, the electroluminescence of the air-gap DBR LED is at a similar current as FIG. 11B. Thus, at the same current, the air-gap DBR LED shows much brighter emission than the normal structure measured before the PEC etching.

Process 4: Fabrication of a 2D PC Air-gap III-Nitride DBR LED Capable of being Optically Pumped.

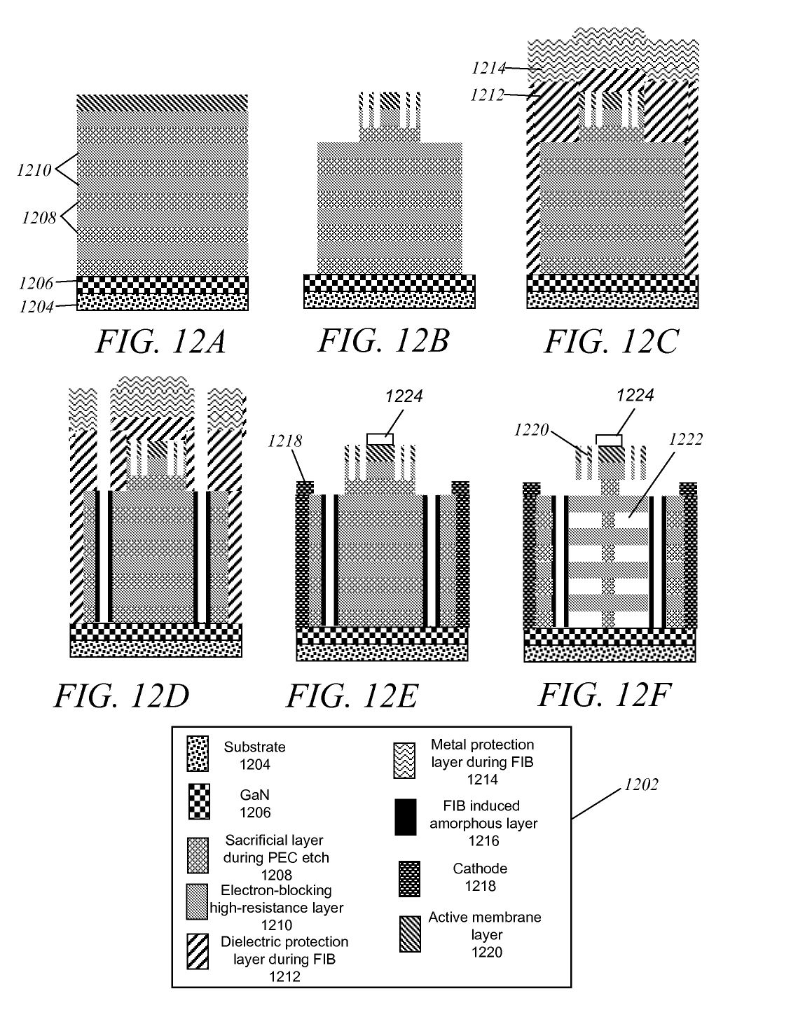

FIGS. 12A-12F are cross-sections showing the layers that illustrates the process followed to fabricate a 2D (two-dimensional) PC air-gap III-nitride DBR LED capable of being optically pumped.

(1) The material structure is shown in FIG. 12A. Each layer is labeled with material composition and doping, as well as layer type. The material is grown by MOCVD on a sapphire substrate 1204. The material may be comprised of 1-2 μm GaN 1206, sacrificial layers 1208 used during a PEC etch (e.g., 100 nm InGaN layers), and electron-blocking high resistance layers 1210 (e.g., 120 nm Al(8%)Ga(92%)N layers).

(2) The mesa structure for the active membrane layer is formed by e-beam-lithography. The typical exposure condition for the 350 nm ZEP520A resist is about 140 μC/cm². The e-beam pattern is transferred to the underlying 50 nm thick SiOₓ layer, which serves as the hard mask for PC patterning by chlorine-based reactive dry-etching technique.

(3) The mesa structure for the bottom DBR (5 period AlGaN/InGaN layer) region 1208/1210 is fabricated by standard photo/e-beam-lithography and chlorine-based reactive dry-etching techniques.

(4) FIG. 12B shows the sample structure after step (2) and step (3).

(5) The dielectric (˜200 nm SiOₓ or SiNₓ) protection layer 1212, and the metallic (˜100 nm Ti) protection layer 1214, are deposited on the sample to prevent any damage by the FIB irradiation, as shown in FIG. 12C.

(6) The FIB milling is performed at ˜30 kV and ˜30 pA. The FIB patterns can be a circular hole, a line, a rectangle, a circular trench, and/or their combination, as shown in FIG. 12D (i.e., as an FIB induced amorphous layer 1216).

(7) The FIB protection layers 1212/1214 are removed using HF.

(8) The sample is annealed at ˜600° C. for 15 minutes to activate the p++GaN 1224 on top of each device.

(9) Using a standard photo/e-beam-lithography and metal lift-off technique, a transparent metal contact 1224 (˜5 nm Pd and ˜10 nm Au) is deposited on the p⁺⁺ GaN, as shown in FIG. 12E. The metal contact 1224 can be replaced by ITO or ZnO materials.

(10) Using a photo-lithography and metal lift-off technique, the cathode 1218 (˜10 nm Ti and ˜300 nm Pt) is deposited around the mesa.

(11) The bandgap selective PEC etching is performed using 1000 W Xe lamp irradiation and the ˜0.004M HCl electrolyte solution in DI water.

(12) FIG. 12F shows the final structure, comprising the active membrane 1220 with InGaN pedestal on top of the air-gap/AlGaN DBR 1222.

Possible Modifications

Several modifications and variations that incorporate the essential elements of this invention are outlined below. Additionally, several alternate materials, conditions and techniques may be used in practice of this invention, as shall be enumerated below.

(1) As an alternative to the FIB treatment, blanket high-energy ion-implantation through a mask can be employed.

(2) An alternate protection layer, such as the spin-on glass, or a different metal layer, and thick photoresist, may be applied during the ion-beam based treatment.

(3) Alternate p-type contact material, such as indium-tin-oxide (ITO), p⁺⁺ GaN, and ZnO, may be used to improve the performance obtained by Pd/Au.

(4) Alternate etching techniques, such as inductively coupled plasma (ICP) etching, may be used to perform the vertical etch.

Advantages and Improvements

General advantages are the selective control of PEC etching, forming local, vertical struts that enhance the structural integrity of membranes, and deeply undercut structures in the III-nitrides, and formed through PEC etching. Specific advantages are as follows:

(1) This is believed to be the first invention that uses the strategic treatment of the material property, in order to ensure the structural stability of the III-nitride-based air-gap nano-architecture, which cannot be achieved through existing wet-etching technique alone. This technique allows the formation of stable, large undercut structures, inhibiting stiction and collapse of membrane structures.

(2) The FIB treatment can enhance the local control of the existing PEC etch process (that mainly relies on the specific placement of the electrode), by introducing the FIB-induced barriers for the carrier diffusion and reaction with electrolyte.

(3) In the case of DBR formation, this process allows for greater light extraction or reflection, with fewer grown hetero-layers, because of the larger contrast in index of refraction. The greater reflection possible enables resonant-enhanced optical devices, providing more efficient light output. For example, this invention has allowed for the fabrication of very high-brightness air-gap DBR light emitting devices, with the five-fold enhancement of the light extraction efficiency.

(4) The present invention can be applied to the fabrication of air-gap microstructures, such as air-gap DBR light emitting diodes, under the current-injection scheme.

(5) The present invention can be applied to the fabrication of air-gap DBR/dielectric VCSEL structures, for example, having low threshold and high speed modulation.

(6) The present invention can be applied to the fabrication of a 2D PC DBR structure.

(7) This present invention can be applied to the fabrication of mechanically tunable III-nitride air-gap DBR structures, mechanically tunable III-nitride air-gap PC DBR structures and mechanically robust undercut III-nitride structures for novel MEMS.

### REFERENCES

The following references are incorporated by reference herein:
1. R. Sharma, E. D. Haberer, C. Meier, E. L. Hu, and S. Nakamura, “Vertically oriented GaN-based air-gap distributed Bragg reflector structure fabricated using band-gap-selective photoelectrochemical etching,” Applied Physics Letters, vol. 87, pp. 051107 (2005).
2. E. D. Haberer, R. Sharma, A. R. Stonas, S. Nakamura, S. P. DenBaars, and E. L. Hu, “Removal of thick (>100 nm) InGaN layers for optical devices using band-gap-selective photoelectrochemical etching,” Applied Physics Letters, vol. 85, pp. 762-4, 2004.
3. E. D. Haberer, R. Sharma, C. Meier, A. R. Stonas, S. Nakamura, S. P. DenBaars, and E. L. Hu, “Free-standing, optically pumped, GaN/InGaN microdisk lasers fabricated by photoelectrochemical etching,” Applied Physics Letters, vol. 85, pp. 5179-81, 2004.
4. Y. Gao, I. Ben-Yaacov, U. K. Mishra, and E. L. Hu, Journal of Applied Physics, vol. 96, pp. 6925-7, 2004.
5. Y.-S. Choi, K. Hennessy, R. Sharma, E. Haberer, Y. Gao, S. P. DenBaars, S. Nakamura, E. L. Hu, and C. Meier, “GaN blue photonic crystal membrane nanocavities,” Applied Physics Letters, vol. 87, pp. 243101, 2005.
6. C. Meier, K. Hennessy, E. D. Haberer, R. Sharma, Y.-S. Choi, K. McGroddy, S. Keller, S. P. DenBaars, S. Nakamura, and E. L. Hu, “Visible resonant modes in GaN-based photonic crystal membrane cavities,” Applied Physics Letters, vol. 88, pp. 031111, 2006.
7. U.S. Pat. No. 5,773,369, issued Jun. 30, 1998 to E. L. Hu and M. S. Minsky, and entitled “Photoelectrochemical wet etching of group III nitrides.”
8. L.-H. Pend, C.-W. Chuang, J.-K. Ho, and Chin-Yuan, “Method for etching nitride,” Unites States: Industrial Technology Research Institute, 1999.
9. A. R. Stonas, P. Kozodoy, H. Marchand, P. Fini, S. P. DenBaars, U. K, Mishra, and E. L. Hu, “Backside illuminated photo-electro-chemical etching for the fabrication of deeply undercut GaN structures,” Applied Physics Letters, vol. 77, pp. 2610-12, 2000.
10. A. R. Stonas, N.C. MacDonald, K. L. Turner, S. P. DenBaars, and E. L. Hu, “Photoelectrochemical undercut etching for fabrication of GaN microelectromechanical systems,” AIP for American Vacuum Soc. Journal of Vacuum Science & Technology B, vol. 19, pp. 2838-41, 2001.
11. A. R. Stonas, T. Margalith, S. P. DenBaars, L. A. Coldren, and E. L. Hu, “Development of selective lateral photoelectrochemical etching of InGaN/GaN for lift-off applications,” Applied Physics Letters, vol. 78, pp. 1945-47, 2001.
12. R. P. Strittmatter, R. A. Beach, and T. C. McGill, “Fabrication of GaN suspended microstructures,” Applied Physics Letters, vol. 78, pp. 3226-8, 2001.
13. U.S. Pat. No. 6,884,470, issued Apr. 26, 2005, to E. L. Hu and A. R. Stonas, and entitled “Photoelectrochemical undercut etching of semiconductor material.”
14. J. Bardwell, “Process for etching gallium nitride compound based semiconductors,” United States: National Research Council of Canada, 2003.
15. U.S. Utility patent application Ser. No. 11/263,314, filed on Oct. 31, 2005, by E. L. Hu, S. Nakamura, E. D. Haberer, and R. Sharma, entitled “Control of photoelectrochemical (PEC) etching by modification of the local electrochemical potential of the semiconductor structures relative to the electrolyte.”
16. T. Fujii, Y. Gao, R. Sharma, E. L. Hu, S. P. DenBaars, and S. Nakamura, “Increase in the extraction efficiency of GaN-based light-emitting diodes via surface roughening,” Applied Physics Letters, vol. 84, pp. 855-7, 2004.
17. U.S. Patent Publication No. US2003/0180980A1, published Sep. 25, 2003, by T. Margalith, L. A. Coldren, and S. Nakamura, entitled “Implantation for current confinement in nitride-based vertical optoelectronics.”
18. C. Youtsey, L. T. Romano, and I. Adesida, “Gallium nitride whiskers formed by selective photoenhanced wet etching of dislocations,” Applied Physics Letters, vol. 68 pp. 1531-3 1996.
19. C. Youtsey, G. Bulman, and I. Adesida, “Dopant-selective photoenhanced wet etching of GaN,” TMS. Journal of Electronic Materials, vol. 27, pp. 282-7, 1998.
20. R. Khare, “The Wet Photoelectrochemical etching of III-V semiconductors,” in Electrical and Computer Engineering, Santa Barbara: University of California, Santa Barbara, pp. 184, 1993.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for enhancing structural integrity of a III-nitride opto-electronic or opto-mechanical air-gap nano-structured device, comprising:
(a) performing an ion beam treatment in a region of the III-nitride opto-electronic or opto-mechanical air-gap nano-structured device, wherein the ion beam treatment locally modifies a material property in the region by making the region resistant to photoelectrochemical (PEC) etching, thereby enhancing the structural integrity; and
(b) performing a band-gap selective PEC etch on the III-nitride opto-electronic or opto-mechanical air-gap nano-structured device, wherein the region is not significantly etched because of the ion beam treatment.

2. The method of claim 1, wherein the ion beam treatment is a focused-ion-beam (FIB) milling.

3. The method of claim 1, wherein the regions comprise supporting struts that enhance the structural integrity of undercut structures of the III-nitride opto-electronic or opto-mechanical air-gap nano-structured device.

4. The method of claim 1, wherein the regions comprise ion-damaged regions.

5. The method of claim 1, wherein the III-nitride opto-electronic or opto-mechanical air-gap nano-structured device is suitably designed for the PEC etching and the ion beam treatment.

6. The method of claim 1, wherein the performing step (b) comprises performing a band-gap selective PEC etch using illumination.

7. The method of claim 1, wherein the performing steps (a) and (b) are used to fabricate an air-gap III-nitride distributed Bragg reflector.

8. The method of claim 7, wherein the III-nitride opto-electronic device is a light emitting diode (LED) including the distributed Bragg reflector.

9. The method of claim 1, wherein the III-nitride opto-electronic device is a light emitting diode (LED) including a two dimensional (2D) photonic crystal (PC).

10. The method of claim 1, further comprising placing a protection layer in selected areas of the III-nitride opto-electronic or opto-mechanical air-gap nano-structured device to prevent the ion beam treatment from damaging optical activity and PEC etch selectivity.

11. The method of claim 1, further comprising annealing the III-nitride opto-electronic or opto-mechanical air-gap nano-structured device for curing material quality after the ion beam treatment.

12. A III-nitride opto-electronic or opto-mechanical air-gap nano-structured device fabricated by the method of claim 1.

13. A method for enhancing structural integrity of a III-nitride opto-electronic or opto-mechanical air-gap nano-structured device, comprising:
(a) performing an ion beam treatment in a region of the III-nitride opto-electronic or opto-mechanical air-gap nano-structured device, wherein the ion beam treatment locally modifies a material property in the region, thereby enhancing the structural integrity; and
